(19) United States
(12) Patent Application Publication
(10) Pub. No.: US 2026/0044084 A1
(43) Pub. Date: Feb. 12, 2026

(54) EXPOSURE DEVICE / TOOL FOR CIRCUITS ON CURVED SURFACES AND METHOD FOR PREPARING CURVED CIRCUITS

(71) Applicant: University of Electronic Science and Technology of China, Chengdu (CN)

(72) Inventors: Yuan LIN, Chengdu (CN); Dengji GUO, Chengdu (CN); Taisong PAN, Chengdu (CN); Min GAO, Chengdu (CN); Guang YAO, Chengdu (CN); Zhenlong HUANG, Chengdu (CN)

(21) Appl. No.: 19/031,948

(22) Filed: Jan. 18, 2025

(30) Foreign Application Priority Data
Aug. 12, 2024 (CN) 2024111007188

(51) Int. Cl. G03F 7/00; G03F 7/16; G03F 7/18

(52) U.S. Cl. CPC G03F 7/70358; G03F 7/168; G03F 7/18; G03F 7/707; G03F 7/70716; G03F 7/70816

(57) ABSTRACT

An exposure device or tool and a method for preparing circuits on curved surfaces, belonging to the technical field of exposure devices and tools, are disclosed. By expanding the designed pattern on the curved surface into multiple, continuous pattern blocks, the original curved pattern is converted into a flat pattern. Based on the flat pattern, a corresponding mask is designed, with the pattern areas retained. Subsequently, using the exposure device or tool, a photoresist on the curved surface is selectively exposed to light, thereby transferring the pattern from the mask to the curved surface. In this exposure process, rotation of the sample stage and horizontal movement of the mask, combined with the light from a light source, allow for the transfer of the pattern from the mask onto the curved sample or workpiece.

### RELATED APPLICATIONS

The present application claims priority to Chinese Pat. Appl. No. 2024111007188, filed Aug. 12, 2024, the contents of which are incorporated by reference herein in their entirety.

### TECHNICAL FIELD

The present invention belongs to the technical field of exposure devices and tools, specifically relating to an exposure device (e.g., a scanner and/or stepper) or tool for making circuits on a curved surface (e.g., a regular curved surface) and a method for preparing such circuits.

### BACKGROUND

Fields such as smart contact lenses, wearable electronics, and conformal antennas often require the fabrication of circuit patterns on curved surfaces. In these fields, curved circuits are typically fabricated by first preparing the circuit patterns on rigid substrates and then transferring them to the curved surface using a transfer technology. However, in this process, the circuit patterns must be designed with stretchable or flexible structures to accommodate deformation during the transfer process, which limits the design of the circuit patterns.

In addition, printing technology is a feasible solution for fabricating curved circuits. To print liquid conductive materials on curved surfaces, a multi-axis (e.g., 5-axis) motion mechanism may control the movement of the printhead on the surface. The equipment for the multi-axis motion mechanism is expensive and requires complex computation programs, further increasing manufacturing costs. Additionally, the point-line-plane molding method used in printing technology has limited efficiency, which poses challenges for mass production.

Furthermore, circuit-scale fabrication typically uses contact exposure and etching methods. However, current exposure devices mainly use flat contact exposure methods, which are not suitable for contact exposure on curved surfaces. Therefore, there is an urgent need for exposure devices that are suitable for processing circuits on curved surfaces.

Thus, the focus of research has shifted to designing contact exposure devices and adopting contact exposure-etching methods to achieve large-scale and efficient fabrication of circuits on curved surfaces (e.g., curved circuits).

### SUMMARY OF THE INVENTION

To address the problems in the background art, objectives of the present invention include providing an exposure device (e.g., a contact exposure device) for circuits on regular curved surfaces and a method for preparing curved circuits. A principle of the exposure device involves unfolding the original regular curved surface pattern along the circumferential direction into a continuous pattern having a funnel or cone shape with convex sides (e.g., a semi-shuttle shape), and exposing each continuous pattern sequentially, ultimately achieving the exposure of the entire pattern.

To achieve the above objectives, the technical solution of the present invention is as follows:

An exposure device or tool (e.g., a contact exposure device) suitable for circuits on regular curved surfaces comprises a rotating sample stage, a light shielding mechanism, and a horizontal moving table.

The rotating sample stage is configured to rotate the sample (or workpiece), the light shielding mechanism is configured to control an exposure area (e.g., on the sample or workpiece), and the horizontal moving table is configured to move a mask plate horizontally. During exposure, the sample surface is exposed by the combined rotation of the sample and the horizontal movement of the mask plate. The sample has a regular curved surface.

Further, the rotating sample stage may include a fixed substrate or support, a first drive mechanism, a first bearing support, a second bearing support, and a rotating support rod.

The first drive mechanism may include a reduction stepper motor, a driving synchronous pulley, a driven synchronous pulley, and a synchronous belt.

The first bearing support, the second bearing support, and the reduction stepper motor may be affixed or secured to the fixed substrate or support (or a surface thereof). The driving synchronous pulley may be on (e.g., affixed or secured to) a shaft of the reduction stepper motor, and a driven synchronous pulley may be on (e.g., affixed or secured to) the rotating support rod. The driven synchronous pulley is connected to the driving synchronous pulley by the synchronous belt. The first bearing support and the second bearing support fix or support the rotating support rod. The reduction stepper motor is configured to rotate (e.g., drive) the rotating support rod via the driving synchronous pulley, the synchronous belt, and the driven synchronous pulley. The sample is fixed at (e.g., connected or secured to) one end of the rotating support rod, and the rotation of the rotating support rod drives rotation of the sample.

Further, the rotational speed of the sample may be adjusted by modifying operational parameters of the reduction stepper motor (e.g., increasing or decreasing its speed).

Further, the light shielding structure may comprise a light shielding plate and a fixing base configured to fix the light shielding plate (e.g., secure the light shielding plate in a predetermined position, from which it generally does not move in the absence of a force on it). The light shielding plate may be fixed or secured to the fixing base, and the fixing base may be fixed, secured or connected to the fixed substrate or support (e.g., the surface thereof).

The light shielding plate may comprise a curved plate, and a surface of the light shielding plate that contacts the sample may be tangent to the surface of the sample. A slit (which may have a funnel or cone shape with convex sides) is in the light shielding plate (e.g., at a center thereof). The light shielding structure ensures that the entire sample is in a darkroom environment, and only the light from an exposure light source passes through the slit to irradiate the surface of the sample.

Further, the slit preferably has a bottom width of 0.1-0.5 mm.

Further, the horizontal moving table may include the mask plate, a mask plate fixing base, a sliding table (e.g., a lead screw slider moving table), and a stepper motor. The stepper motor may be connected through a coupling to a lead screw in the lead screw slider moving table. The mask plate fixing base may be fixedly connected to the sliding table (e.g., a surface of the sliding table). The mask plate may be fixed on or secured to a curved fixing surface of the mask plate fixing base, and the mask plate may comprise a substrate with an exposure pattern therein.

The stepper motor may be configured to drive (e.g., rotate) a lead screw in (e.g., passing through) the sliding table via the coupling. Rotation of the lead screw drives the slider to reciprocate on a guide rail (e.g., in the sliding table). The mask plate fixing base moves under a sliding drive (e.g., in response to movement of the slider), and the mask plate moves reciprocally under the drive (e.g., in response to movement) of the mask plate fixing base. The mask plate may be in full contact with an outer surface of the light shielding plate.

Further, the pattern (e.g., an exposure pattern) on the mask plate may comprise the curved surface, unfolded into an overall continuous pattern (which, in the case of a regular curved surface, approximates a pattern of side-by-side funnel or cone shapes with convex sides). The mask plate pattern may be designed and/or processed according to (e.g., laid out on) the unfolded continuous pattern. The mask plate may have a substrate that preferably comprises a transparent material, and an opaque ink is on (e.g., printed on) the surface of the transparent material in (e.g., to form) the exposure pattern. Since the exposure light source cannot pass through the opaque ink areas, the transparent regions define the exposure pattern.

Further, the mask plate substrate preferably comprises a material such as a polyester (e.g., polyethylene terephthalate [PET]), polypropylene (PP), polyvinyl chloride (PVC), a polycarbonate (PC), or polystyrene (PS), which may have a thickness of 100-200 μm.

Further, the sample may be spherical or elliptical, or comprise a partial sphere or ellipse (e.g., a truncated sphere or ellipse).

Further, the curved surface may correspond to a direction (e.g., a certain or predetermined direction) of a circumference of the sphere or ellipse, where a center of the circumference coincides with a center or origin of the sphere or ellipse.

The invention also provides a method for preparing a curved circuit (e.g., using the above-described exposure device or tool), including the following steps:

Step 1: Immerse a sample or workpiece having a curved surface in a photosensitive ink (e.g., a photoresist) and ensure the curved surface of the sample is in contact with the ink, and then cure the ink-coated sample in an oven. The material of the sample may comprise a polyimide (PI)-copper-clad laminate (e.g., comprising a polyimide layer on the sample and a copper layer on the polyimide layer; further embodiments may comprise one or more further bilayers of alternating polyimide and copper layers).

Step 2: Fix or attach the sample coated with photosensitive ink from Step 1 to a rotating support rod in the exposure device or tool.

Step 3: Expose the sample coated with photosensitive ink (e.g., to light) as follows: rotate the sample using a reduction stepper motor, while moving a mask plate horizontally along a guide rail using a stepper motor, expose a pattern on the mask plate sequentially (e.g., with light) through a slit on a light shielding plate in the exposure device or tool, thereby transferring the pattern from the mask plate to the photosensitive ink layer on the sample. The curved sample may be driven by a rotating sample stage at a rotation speed equal to a movement speed of the horizontal moving table in the exposure device or tool. The movement speed of the horizontal moving table may be a horizontal displacement speed, and the speed of the curved sample may be a linear speed.

Step 4: Develop, etch, and strip the sample exposed in Step 3 to obtain the desired patterned circuit (or circuit layer) on the sample.

The mechanism of the invention is as follows. By unfolding the designed pattern on the curved surface into multiple continuous convex funnel- or cone-shaped blocks, the curved pattern can be transformed into a flat or substantially flat pattern. The corresponding mask plate is designed according to the converted flat pattern, where in one case (e.g., using a negative photoresist), the retained pattern areas are transparent, and the other areas are opaque. Alternatively (e.g., using a positive photoresist), the retained pattern areas are opaque, and the other areas are transparent. The exposure device then transfers the pattern from the mask plate onto the regular curved surface by exposing the photosensitive ink or photoresist on the curved surface. In this exposure process, the combined rotation of the sample stage and the horizontal movement of the mask plate, along with the dose of radiation from the light source, achieve the transfer of the pattern from the mask plate onto the coated sample.

In conclusion, due to the adoption of the above technical solutions, the beneficial effects of the invention are as follows:

The present exposure device and method unfold the original curved surface pattern (e.g., along the circumference when the original curved surface is a sphere or an ellipse) into a continuous and/or repeated pattern blocks (which may have funnel or cone shape with convex sides). By sequentially exposing each block in the continuous and/or repeated pattern, the entire pattern is ultimately exposed, enabling the preparation of curved circuit patterns and laying the foundation for the preparation of circuits on curved surfaces.

### BRIEF DESCRIPTION OF THE DRAWINGS

FIG. 1 is a schematic diagram of the overall structure of an exemplary exposure device or tool for forming circuits on regular curved surfaces, in accordance with the present invention.

FIG. 2 is a schematic diagram of an exemplary rotating sample stage in accordance with the present invention.

FIG. 3 is a schematic diagram of an exemplary light shielding mechanism in accordance with the present invention.

FIG. 4 is a schematic diagram of an exemplary

horizontal moving table and an exemplary mask plate in accordance with the present invention.

FIG. 5 is a schematic diagram of a contact lens with an exemplary inductive coil in accordance with Example 3 of the present application.

FIG. 6 shows an exemplary continuous semi-shuttle-shaped pattern (i.e., having a funnel or cone shape with convex sides) obtained by unfolding the contact lens with an inductive coil in accordance with Example 3.

FIG. 7 is a schematic diagram of an exemplary spherical antenna array in accordance with Example 4 of the present application.

Reference Markings 1: Rotating Sample Stage; 101: Spherical Sample; 102: Rotating Support Rod; 103: First Bearing Support; 104: Driven Synchronous Pulley; 105: Synchronous Belt; 106: Second Bearing Support; 107: Reduction Stepper Motor; 108: Driving Synchronous Pulley; 109: Fixed Substrate or support; 2: Light Shielding Structure; 201: Light Shielding Plate; 202: Light Shielding Plate Fixing Base; 3: Horizontal Moving Table; 301: Mask Plate Fixing Base; 302: Mask Plate; 303: Lead Screw Slider Moving Table; 304: Stepper Motor; 4: Smart Contact Lens; 401: Dielectric Layer (e.g., silicone rubber); 402: Copper Inductive Coil; 5: Spherical Antenna; 501: Spherical Dielectric (e.g., epoxy resin); 502: Spherical Antenna Array.

### DETAILED DESCRIPTION OF EMBODIMENTS:

To make the objectives, technical solutions, and advantages of the present invention clearer, the following detailed description is provided in conjunction with the embodiments and accompanying figures.

### Embodiment 1

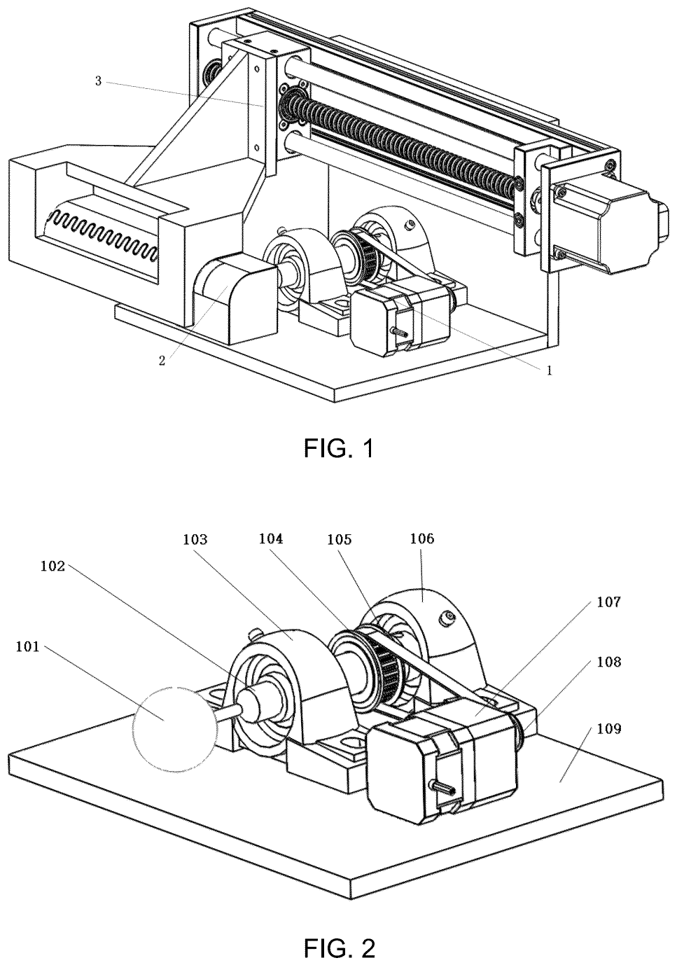

For curved surfaces such as spherical surfaces, the present exposure device or tool for spherical circuits may have the overall exemplary structure shown in FIG. 1, which includes a rotating sample stage 1, a light shielding mechanism 2, and a horizontal moving table for the mask plate 3.

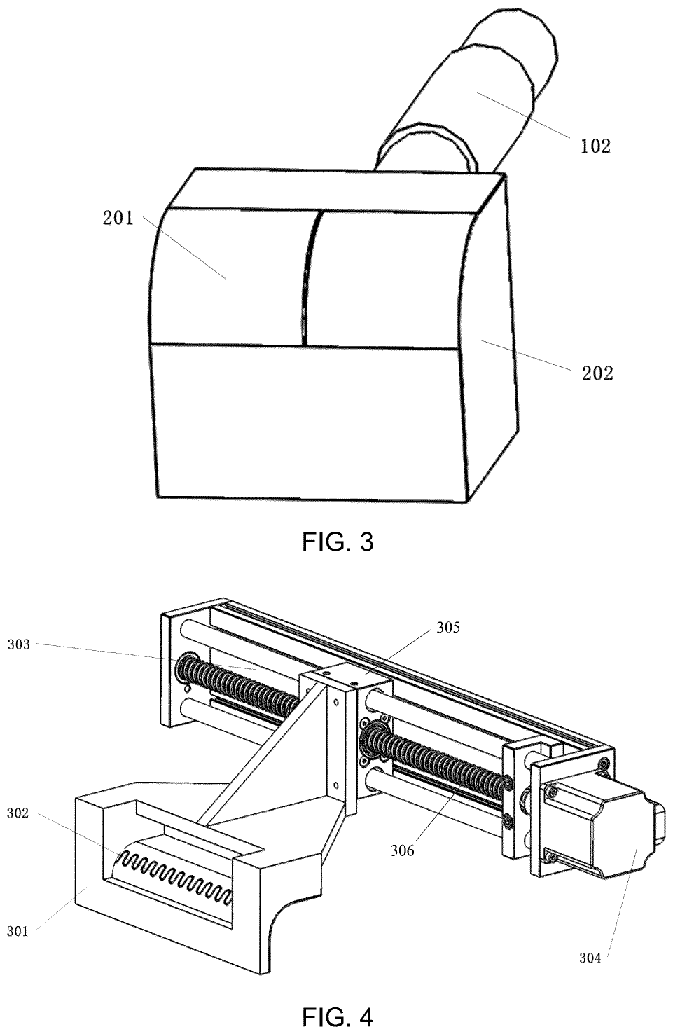

The structure of the exemplary rotating sample stage 1 is shown in FIG. 2, and it includes a rotating support rod 102, a first bearing support 103, a second bearing support 106, a driven synchronous pulley 104, a synchronous belt 105, a driving synchronous pulley 108, a reduction stepper motor 107, and a fixed substrate or support 109. A sample 101 (which may be spherical) is mounted at an exposed or extended end of the support rod 102.

In one example, the sample 101 is fixed to the end of the support rod 102 by threading, although other mounting mechanisms (pressure fit, tongue-in-groove, etc.) may also be used. The support rod 102 passes through the first bearing support 103 and the second bearing support 106. The driven synchronous pulley 104 is fixed to the support rod 102 using, for example, a first set screw. The driven synchronous pulley 104 is connected to the driving synchronous pulley 108 by the belt 105. The driving synchronous pulley 108 is fixed to the shaft of the reduction stepper motor 107 using, for example, a second set screw. The first bearing support 103, the second bearing support 106, and the reduction stepper motor 107 are all fixed or secured to the substrate 109.

The reduction stepper motor 107 drives the rotation of the sample 101 by rotating the driving synchronous pulley 108, which advances the belt 105, which rotates the driven synchronous pulley 104 and the support rod 102. The reduction stepper motor 107 may have an adjustable rotation speed, step angle and/or frequency for rotating the sample 101.

The exemplary light shielding structure 2 is shown in FIG. 3 and includes a light shielding plate 201 and a light shielding plate fixing base 202.

The light shielding plate 201 comprises a curved plate opaque to the exposure light wavelength(s) (e.g., comprising stainless steel), and may have a thickness of at least 0.005 mm (e.g., 0.01 mm, up to 1-2 mm). It has a slit therein (not shown, but having, e.g., a funnel or cone shape with convex sides), and the slit may have a width of 0.01-0.05 mm at its center (e.g., midway along its longest dimension). The exposure light from a light source (not shown, but having a wavelength in the range of 193-436 nm) passes through this slit to contact the surface of the spherical sample 101. The light shielding plate 201 may be tangent to the surface of the sample 101, meaning that the light shielding plate 201 may contact the sample 101, and at the contact point(s), the curvature of the light shielding plate 201 may match the curvature of the sample surface.

The light shielding plate 201 is on (e.g., fixed or secured to) the light shielding plate fixing base 202, which may have from three to five sides. The top and optional bottom sides may be rectangular and parallel to each other, and the top side may be narrower than the bottom. The optional front side may have a rectangular shape, in which one edge is perpendicular to and/or fixed to the bottom. The opposite edge, parallel to the first edge, may be connected or adjacent to an edge of the light shielding plate 201. Alternatively, the light shielding plate 201 may extend to the bottom of the light shielding plate fixing base 202 (which contacts the substrate/support 109). The two vertical sides of the fixing base 202 may be fixed or secured to the top and optional bottom and front sides, forming the sample exposure chamber (e.g., together with the light shielding plate 201). The sample 101 is placed inside the exposure chamber, and the mask plate is positioned outside the exposure chamber (e.g., on the outer surface of the light shielding plate 201). The light shielding plate fixing base 202 is fixed or secured to the substrate or support 109.

The light shielding plate 201 is replaceable. On the one hand, the size of the slit in the light shielding plate affects the exposure rate. For example, smaller slits require more time to complete the exposure. Therefore, the slit size should be determined based on actual needs (e.g.,. On the other hand, different curved surfaces require different sizes and/or shapes of light shielding plates. The larger the curvature arc or radius of the curved surface, the larger the light shielding plate. Thus, the appropriate light shielding plate should be chosen according to the size of the sample being tested and/or the shape of the curved surface of the sample. The curved surface of the sample is preferably regular (e.g., having an axis and/or plane of symmetry), but the invention is applicable to other curved surfaces.

The structure of the horizontal moving table for the mask plate 3 is shown in FIG. 4, and it may include a mask plate fixing base 301, a sliding table (e.g., lead screw slider moving table) 303, and a stepper motor 304. Some embodiments of the horizontal moving table may also include the mask plate 302. The mask plate 302 is fixed to a curved fixing surface on or in the mask plate fixing base 301. The mask plate fixing base 301 is fixed to a surface of the slider 305 in or on the sliding table 303, and the slider 305 is mounted on the lead screw 306. The stepper motor 304 drives (e.g., rotates) the lead screw 306 via a coupling (not shown), and rotation of in turn the lead screw 306 drives (e.g., moves) the slider 305. The mask plate fixing base 301 is moved by the slider 305, thereby driving (e.g., moving) the mask plate 302. The mask plate 302 may contact the curved (e.g., outer) surface of the light shielding plate 201, without any gap.

The mask plate 302 may comprise a transparent material (e.g., polyethylene terephthalate [PET]) and may have a thickness of 0.05-0.5 mm (e.g., 0.2 mm). A black exposure pattern is printed on the surface of the mask plate 302. The exposure light (e.g., radiation) from the light source cannot pass through the black exposure pattern.

### Example 2

A method for preparing curved circuits using an exposure device or tool may comprise the following steps.

Step 1: A sample 101 with a photosensitive blue oil (e.g., photoresist) coating on its surface is fixed onto a rotating support rod 102. The sample in this example comprises an insulating, spherical substrate with a copper layer on its surface, and the photosensitive blue oil is coated onto the exposed surface of the copper layer.

Step 2: The exposure slit of the light shielding plate 201 is tangentially in contact with the surface of the spherical sample 101. For example, the support rod 102 may be moved so that the spherical sample 101 is brough into contact with the light shielding plate 201 at the location of the slit, and so that the support rod 102 remains horizontal with respect to the support 109 and perpendicular with respect to the front side of the light shielding plate fixing base 202. Alternatively, the position (and optionally the height) of the light shielding plate fixing base 202 on the support 109 may be adjustable, and the light shielding plate fixing base 202 can be brought into a position in which the slit in the light shielding plate 201 can contact the sample 101.

Step 3: A mask plate 302 (e.g., a PET substrate with an opaque ink thereon in a pattern corresponding to part or all of the circuit) is fixed onto the mask plate fixing base 301 so that it can be brought into seamless (e.g., gapless) contact with the light shielding plate 201.

Step 4: An external light source (e.g., a source of ultraviolet light outside, but proximate to the mask plate 302 and the slit in the light shielding plate 201) is turned on, and the rotating sample stage 1 and the horizontal moving table of the mask plate 3 are simultaneously activated. The mask plate 302 moves at a constant speed from one side of the exposure slit of the light shielding plate 201 to the other side under the drive of the stepper motor 304. Meanwhile, the rotating sample stage 1 drives the spherical sample 101 to rotate at the same speed as the horizontal moving table 3. Alternatively, the stepper motor 304 and the reduction stepper motor 107 can respectively move the mask plate 302 and rotate the sample 101 in simultaneous increments or steps, pausing or delaying between successive increments or steps for a predetermined period of time (e.g., sufficiently long for the light to change the solubility characteristic of the ink or photoresist on the sample in the developer), as is known in the art. The movement speed of the horizontal moving table 3 is the horizontal displacement speed, and the speed of the spherical sample 101 is the linear velocity.

Step 5: After the entire pattern (e.g., on the mask plate 302) is exposed to the sample, the exposure light source is turned off. Then, the rotating sample stage 1 and the horizontal moving table 3 are returned to their initial and the spherical sample is removed to obtain a spherical copper-clad sample pattern thereon with a corresponding to that on the mask plate 302.

### Example 3

A method for manufacturing smart contact lenses with an inductive coil thereon may comprise the following steps.

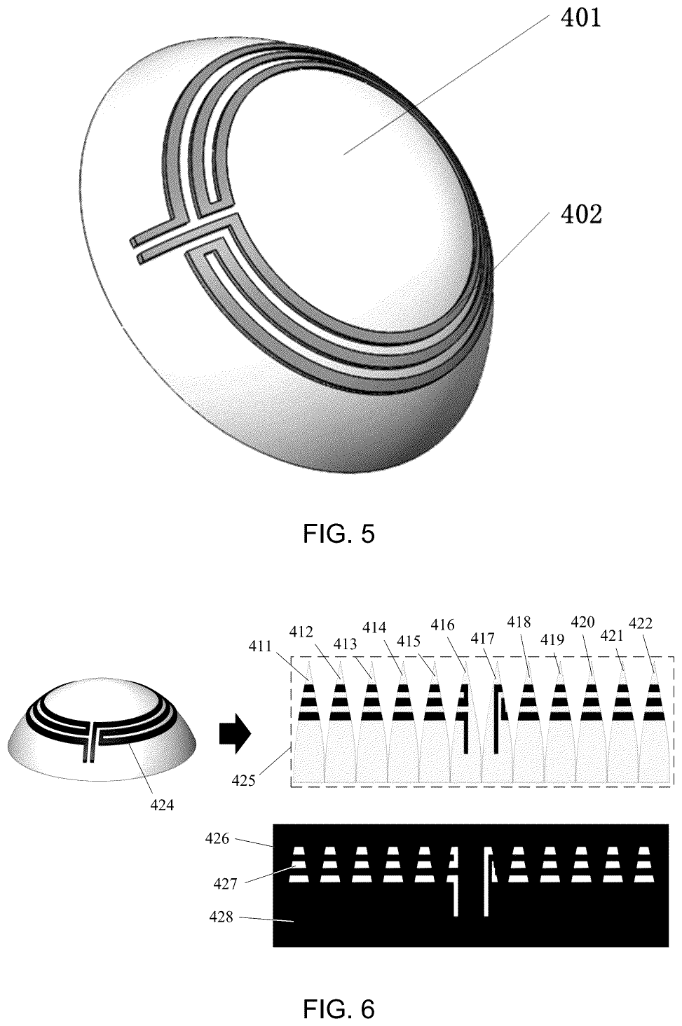

Step 1: The structure of the smart contact lens with an inductive coil is shown in FIG. 5. A silicone rubber lens 401 is prepared on a regular curved surface using the contact lens mold. Conductive graphene is sprayed onto the surface of the silicone rubber lens 401, and it is dried. The thickness of the graphene is over 20 microns, and the square resistance of the conductive graphene on the silicone rubber lens 401 is greater than 20 ohms/cm. The conductive graphene in this example is from a water-based ink comprising graphene and/or carbon nanotubes obtained from Suzhou Tanfeng Graphene Technology Co., Ltd.

Step 2: The conductive graphene-coated silicone rubber lens 401 from Step 1 is immersed in a copper electroplating solution for electroplating. The electroplating time is 3 hours, and the electroplating current is 2 A/dm². The area with conductive graphene is electroplated with copper. After electroplating, a layer of electroplated copper having a thickness of about 12 μm is formed on the surface of the silicone rubber lens 401. The electroplating solution used in this example was obtained from LPKF Laser & Electronics SE, with the main component being copper sulfate.

Step 3: The sample from Step 2 is immersed in a photosensitive ink, thereby coating the surface of the copper with the photosensitive ink, which naturally levels out, forming a substantially uniform coating on the copper layer.

Step 4: The sample from Step 3 is dried at 100° C. for 10 minutes.

Step 5: The dried sample from Step 4 is secured to the end of a rotating support rod. In one example, a spherical support (e.g., that is transparent to the wavelength[s] of the exposure light) having a curvature matching that of the inner surface of the lens 401 is secured to the end of the support rod, and the dried sample from Step 4 is reversibly adhered to the end of the spherical support (e.g., so that the center of the lens 401 is at a location directly opposite from the support rod).

Step 6: The sample at the end of the support rod from Step 5 is exposed to light through a mask using the exemplary apparatus of FIG. 1. The contact lens pattern is expanded into multiple continuous curved funnel- or cone-shaped pattern blocks 411-422, as shown in FIG. 6, converting the original or target curved pattern 424 into a flat pattern 425. Based on the converted flat pattern 425, a corresponding mask 426 is designed. In the mask 426, the white areas 427 are transparent, as the mask base (or material) itself is transparent to the exposure light. The black area(s) 428 in the mask are created by printing an opaque ink (e.g., carbon black ink) according to the flat pattern 425 on the transparent substrate. The black printed area(s) 428 on the mask substrate are opaque, and the exposure light cannot pass through them, while the light can pass through the transparent areas 427 in the exposure pattern 426 shown in FIG. 6.

The exposed sample undergoes development, etching, and de-coating (stripping or removal of the remaining photoresist) in accordance with known processes. Development refers to the process where the pattern on the mask is transferred to the photosensitive ink. In this example, the photosensitive ink in the exposed areas undergoes photopolymerization (curing), making it resistant to the developer, while the unexposed (non-irradiated) photosensitive dry film is subsequently dissolved in a developer. The developer in this example may comprise a sodium carbonate solution. After development, the copper layer under the non-irradiated area(s) of the photosensitive ink is exposed.

Etching refers to the process where an etching solution (in this example, comprising an ammonium persulfate solution) reacts chemically with copper to etch or remove the exposed area(s) of the copper layer. After development, the copper layer to be removed will be exposed, while the copper layer in the irradiated area(s) is protected by the cured photosensitive ink, preventing contact with the etching solution. After a certain amount of time, the sample will retain only the desired copper pattern.

De-coating involves using a de-coating solution (e.g.,. comprising aqueous sodium hydroxide as a main component) to strip or remove the cured photosensitive ink from the copper layer surface. This results in the final copper inductive coil 402 on the smart contact lens.

The smart contact lens 401 with the inductive coil 402 thereon prepared in this example can be used to measure the intraocular pressure of an eye.

### Example 4

A method for preparing a curved circuit applied to a spherical antenna array may comprise the following steps.

Step 1: An ink (e.g., solution or suspension) of conductive graphene is sprayed onto the surface of a spherical dielectric sample 501 (e.g., comprising an epoxy resin) and dried.

Step 2: The spherical sample 501 with sprayed conductive graphene is immersed in a copper electroplating solution for electroplating. The electroplating time is 3 hours, and the electroplating current is 2 A/dm². After electroplating, a layer of electroplated copper having a thickness of about 12 μm is on the surface of the spherical sample 501.

Step 3: The sample from Step 2 is immersed in a photosensitive ink, and the surface of the copper is coated with photosensitive ink, which then naturally levels out, forming a substantially uniform coating on the copper layer.

Step 4: The sample from Step 3 is dried at 100° C. for 10 minutes.

Step 5: The sample from Step 4 is fixed or connected to the stage (e.g., the rotating support rod) of the exposure device or tool (e.g., for making circuits on curved surfaces).

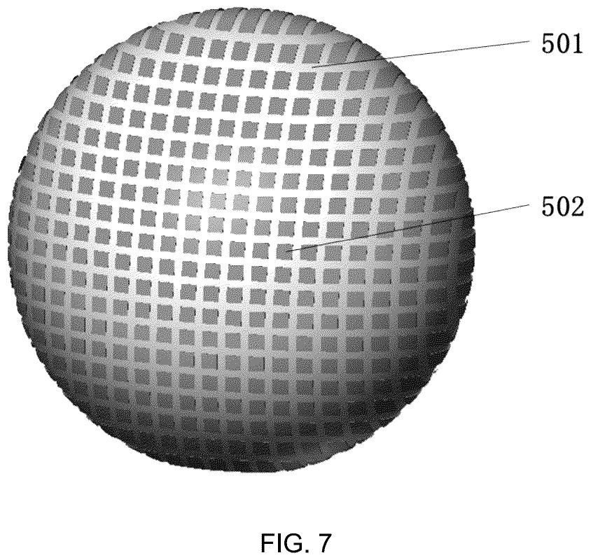

Step 6: The sample from Step 5 is exposed (e.g., to UV light passed through a mask having a pattern thereon and a slit in the light shielding structure), and the exposed sample undergoes development, etching, and de-coating. This results in the preparation of a spherical antenna array 502 on the spherical sample 501, as shown in FIG. 7.

What is claimed:

1. An exposure device or tool for circuits on curved surfaces, comprising a rotating sample stage, a light shielding mechanism, and a horizontal moving table, wherein:
the rotating sample stage is configured to rotate a sample, the light shielding mechanism is configured to control an exposure area, and the horizontal moving table is configured to move a mask plate horizontally;
during exposure, a surface of the sample is exposed by horizontal movement of the mask plate and rotation of the sample; and
the sample has a curved surface.

2. The exposure device or tool as claimed in claim 1, wherein the sample is spherical or elliptical, and the curved surface is a regular curved surface.

3. The exposure device or tool as claimed in claim 2, wherein the regular curved surface is in a circumferential direction of the sample, the sample has a center and a circumference, and the circumference has a center that aligns with the center of the sample.

4. The exposure device or tool as claimed in claim 1, wherein the rotating sample stage comprises a fixed substrate or support, a first driving mechanism, a first bearing support, a second bearing support, and a rotating support rod;
the first driving mechanism comprises a reduction stepper motor, a driving synchronous pulley, a driven synchronous pulley, and a belt;
the first bearing support, the second bearing support, and the reduction stepper motor are on the surface of the fixed substrate or support;
the driving synchronous pulley is on a shaft of the reduction stepper motor, the driven synchronous pulley is on the rotating support rod, and the driven synchronous pulley is connected to the driving synchronous pulley via the belt;
the first bearing support and the second bearing support fix or support the rotating support rod;
the reduction stepper motor is configured to rotate the rotating support rod via the driving synchronous pulley, the belt, and the driven synchronous pulley; and
the sample is fixed at one end of the rotating support rod, and the rotating support rod drives rotation of the sample.

5. The exposure device or tool as claimed in claim 4, wherein, during rotation of the sample, the sample has a linear velocity equal to a horizontal displacement velocity of the mask plate.

6. The exposure device or tool as claimed in claim 1, wherein the light shielding mechanism comprises a light shielding plate and a light shielding plate fixing base;
the light shielding plate is fixed or secured to the light shielding plate fixing base, and the light shielding plate fixing base is on the fixed substrate or support;
the light shielding plate comprises a curved plate having a slit therein; and
the light shielding mechanism is configured so that the sample is in a darkroom environment, with only light from an exposure source passing through the slit to irradiate a surface of the sample.

7. The exposure device or tool as claimed in claim 6, wherein the light shielding plate and the light shielding plate fixing base are configured to form a box-like structure with one open side, the sample is inside the box-like structure through the open side, and the sample makes contact with an inner surface of the light shielding plate.

8. The exposure device or tool as claimed in claim 6, wherein the slit has a width determined based on actual needs.

9. The exposure device or tool as claimed in claim 6, wherein the slit has a funnel or cone shape with convex sides.

10. The exposure device or tool as claimed in claim 9, wherein the slit has a bottom width of 0.1-0.5 mm.

11. The exposure device or tool as claimed in claim 1, wherein the horizontal moving table comprises a mask plate, a mask plate fixing base, a screw slide table, and a stepper motor;
the stepper motor is connected to a screw in the screw slide table via a coupling;
the mask plate fixing base is connected to a slider of the screw slide table;
the mask plate is on a curved fixing surface of the mask plate fixing base, and the mask plate comprises a substrate with an exposure pattern thereon;
the stepper motor is configured to rotate the screw through the coupling, which in turn drives the slider to move back and forth;
the mask plate fixing base moves as the slider moves; and
the mask plate moves back and forth as driven by the mask plate fixing base, and the mask plate fits an outer surface of the light shielding plate.

12. The exposure device or tool as claimed in claim 1, wherein the exposure pattern comprises the curved surface, unfolded into a continuous pattern, and the exposure pattern is designed and/or processed according to the unfolded continuous pattern.

13. The exposure device or tool as claimed in claim 12, wherein the mask plate comprises a transparent substrate with an opaque ink in the exposure pattern thereon.

14. The exposure device or tool as claimed in claim 13, wherein the transparent substrate comprises a polyester, polypropylene, polyvinyl chloride, a polycarbonate, or polystyrene.

15. The exposure device or tool as claimed in claim 13, wherein the transparent substrate has a thickness of 100-200 μm.

16. A method for preparing a curved circuit using an exposure device or tool suitable for circuits on curved surfaces, comprising:
immersing a sample in a photosensitive ink to form an ink-coated sample, and curing the ink-coated sample in an oven;
fixing or attaching the cured ink-coated sample onto a rotating support rod of the exposure device or tool;
exposing the cured ink-coated sample by rotating the cured ink-coated sample with reduction stepper motor while moving a mask plate horizontally with a horizontal moving table, and exposing a pattern on the mask plate sequentially through a slit on a light shielding plate in the exposure device or tool to transfer the pattern from the mask plate to the cured ink on the sample; and
developing, etching, and stripping the exposed sample, thereby obtaining the curved circuit on the sample.

17. The method as claimed in claim 16, wherein the ink-coated sample is cured at a temperature of 80-100° C. for a time of 10-20 minutes.

18. The method as claimed in claim 16, wherein the cured ink-coated sample rotates at a same speed as the mask plate is moved horizontally.

19. The method as claimed in claim 16, wherein the sample has a regular curved surface, and the pattern is transferred from the mask plate to the cured ink on the regular curved surface of the sample.
